(19) United States
(12) Patent Application Publication
(10) Pub. No.: US 2025/0073994 A1
(43) Pub. Date: Mar. 6, 2025

(54) METHOD FOR CREATING A THREE-DIMENSIONAL STRUCTURE, AND LASER LITHOGRAPHY DEVICE

(71) Applicant: Nanoscribe Holding GmbH, Eggenstein-Leopoldshafen (DE)

(72) Inventors: Matthias Blaicher, Stutensee (DE); Yilin Xu, Wannweil (DE)

(21) Appl. No.: 18/795,386

(22) Filed: Aug. 6, 2024

(30) Foreign Application Priority Data
Aug. 31, 2023 (DE) 10 2023 123 551.6

(51) Int. Cl. B29C 64/273; B23K 26/342; B29C 64/135; B29C 64/393; B33Y 10/00; B33Y 30/00; B33Y 50/02

(52) U.S. Cl. CPC B29C 64/273; B23K 26/342; B29C 64/135; B29C 64/393; B33Y 10/00; B33Y 30/00; B33Y 50/02

(57) ABSTRACT

A method for creating a three-dimensional structure in a lithographic material (12), the method comprising the following steps: holding the lithographic material (12) by means of a lithographic material holder (14); generating an input laser beam (20) by means of a laser beam source (18); demultiplexing the input laser beam (20) for temporally splitting the input laser beam (20) in order to form a plurality of laser writing beams (26); focusing the plurality of laser writing beams (26) by means of an objective (70); creating the three-dimensional structure in the lithographic material (12) by means of the focused laser writing beams (26).

### FIELD

This disclosure relates to a method for creating a three-dimensional structure, and a laser lithography device.

### BACKGROUND

The technique referred to in the present context of laser lithography is also referred to, for example, as stereolithography or direct laser writing. With this technique, structures are written into a generally initially liquid photosensitive substance, which is referred to in the present context as lithographic material, by means of a laser writing beam. In the process, a solidification effect is locally triggered in the lithographic material by the laser writing beam. The solidification takes place, for example, due to a local polymerization of the lithographic material induced by photon absorption. In the field of optical lithography, such a lithographic material is also referred to as photoresist. In the field of stereolithography, this is also referred to as resin.

The technique of laser lithography or of direct laser writing is advantageously used in the production of micro- or nanostructures when high precision is desired and at the same time freedom of design and flexibility in shaping is to be maintained. In contrast to, for example, the method of mask lithography, different structures can namely be written without the structure being dictated by a mask or the like.

Various techniques are known here which can, to a varying extent, lead to a direct contact between the focusing optics or its optical terminating element and the lithographic material. Firstly, in principle, it is known that the desired overall structure is produced by sequentially writing a series of partial structures (for example, in layers or slices) which then overall complement one another to form the desired structure.

In one type of known techniques, the writing beam strikes the surface of a volume of lithographic material and leads to local solidification on the surface. As a rule, these methods are based on linear processes such as one-photon absorption and the resulting local change of the lithographic material. To write three-dimensionally extended structures, in such methods, after writing a layer in an application step, an additional layer of lithographic material is applied. This can be achieved, for example, in that a substrate with the structure to be written thereon is gradually lowered into a bath of lithographic material, and the structuring takes place in each case by means of the writing beam on the surface. In such techniques, it can happen that the terminating element of the focusing optics comes into contact with lithographic material.

Another approach uses the physical principle of two-photon polymerization or multi-photon polymerization in general to achieve solidification of lithographic material even within a volume of lithographic material, i.e., also below the surface. This is made possible in that writing beam and lithographic material are coordinated with one another such that a solidification effect takes place with the involvement of non-linear effects. For example, the writing beam is selected in a spectral range which normally cannot trigger a solidification effect in the lithographic material. For example, the lithographic material and the writing beam can be coordinated in such a way that induced solidification only occurs upon absorption of two or more photons of the writing beam (two-photon polymerization or multi-photon polymerization). In the present context, the term multi-photon polymerization denotes induced polymerization by absorption of two or more than two photons. In this respect, the term “multi-photon absorption” also includes the process of “two-photon absorption” and “two-stage absorption” for the present description. The conditions required for multi-photon polymerization are generally only achieved in a zone of increased intensity. This increased intensity zone is typically provided in an area of a focus of the laser writing beam. In this respect, the focus is a beam waist of the laser writing beam which is produced by suitable optics (e.g. beam guiding optics, beam-shaping optics and/or an objective). For lithographic production of extended 3D structures, the focus can then be moved through a volume of lithographic material in accordance with geometry description data and trigger a solidification process locally.

The production of three-dimensional structures using two-photon polymerization is often carried out at a working distance of 100 μm (micrometers) to 20 mm (millimeters). The working distance is a distance between the focus and an optical terminating element of an objective for producing the focus. At such low working distances, a contact of the lens with the lithographic material can often not be prevented. In particular, the objective dips into the lithographic material. A production method in which the lens dips at least partially into the lithographic material can also be referred to as dip-in multi-photon polymerization. Here, during the production of three-dimensional structures, the lithographic material frequently gets onto the objective and in particular onto the optical terminating element.

Regardless of the specific technique, one challenge is that the writing process for complex structures can be time-consuming and speeding this up should usually not come at the expense of precision.

EP 4 163 083 A1 discloses a device for the lithography-based production of a three-dimensional component. The device has a beam splitter for splitting an input beam into a plurality of beams that are focused on focal points within a material. In addition, the device has a number of acousto-optic modulators corresponding to the number of beams. An acousto-optic modulator is arranged in each beam path to shift the focal point of that particular beam.

### SUMMARY

This disclosure is based on the object of making possible, in particular, a rapid production of three-dimensional structures by using laser lithography technology.

This object is achieved by a method with the features of claim 1 and by a laser lithography device with the features of claim 8. Advantageous and preferred embodiments of this disclosure are contained in the additional claims.

The method according to this disclosure for creating a three-dimensional structure in a lithographic material comprises the steps of: holding the lithographic material by means of a lithographic material holder; generating an input laser beam by means of a laser beam source, wherein the laser beam propagates in a propagation direction; forming a plurality, in particular three, four or five, laser writing beams by demultiplexing the laser beam by means of a demultiplexer unit that is arranged between the laser beam source and an objective; focusing the plurality of laser writing beams by means of the objective; creating the three-dimensional structure in the lithographic material by means of the focused laser writing beams.

By demultiplexing the laser beam, a plurality of laser writing beams are created, wherein the three-dimensional structure can then be created by means of the plurality of laser writing beams. This reduces the time required to move the lithographic material relative to a laser writing beam, and thus makes possible a particularly rapid production of the three-dimensional structure.

The division of the laser writing beam by temporal demultiplexing can bring particular advantages for laser lithography when two-photon polymerization or multi-photon polymerization is used. The lithographic material is converted into an exposed state, in particular polymerized or solidified, due to a non-linear process. For this reason, when a pulsed laser beam is used, the peak power of the individual laser pulses of the laser beam is a relevant variable for the process of two-photon polymerization or multi-photon polymerization. By the temporal demultiplexing of the laser beam, laser writing beams are created that have a higher peak power than laser writing beams created by continuous beam splitting, for example by means of a beam splitter. Continuous beam splitting can be understood as temporally continuous beam splitting or passive continuous beam splitting. Continuous beam splitting can be achieved using a passive optical element. Temporal demultiplexing thus improves process efficiency in two-photon polymerization or multi-photon polymerization.

The laser beam source can be designed as a laser diode.

The laser writing beams strike the lithographic material or are focused into the lithographic material. The laser writing beams and the lithographic material can be coordinated with one another in such a way that the lithographic material can be transferred into an exposed state, in particular polymerized or solidified, locally within a plurality of regions in or around the particular foci of the laser writing beams in order to create the three-dimensional structure by means of multi-photon polymerization.

The laser writing beams can pass through a frequency doubling apparatus for doubling a frequency of the laser writing beams. The frequency doubling apparatus can be arranged between the waveguide arrangement and the objective. The frequency doubling apparatus can comprise a nonlinear crystal, for example a lithium niobate crystal. The non-linear crystal can be arranged in phase with the laser writing beams such that at least a portion of each laser writing beam is frequency doubled after passing through the non-linear crystal. The frequency doubling apparatus can be held by a holding matrix.

The lithographic material holder can be designed to hold the lithographic material for the purpose of creating the three-dimensional structure. In particular, it is provided that the lithographic material holder can hold a volume of lithographic material in such a way that the laser writing beams can be focused into the lithographic material. The lithographic material holder can hold the lithographic material in such a way that the objective can be immersed in the lithographic material for the purpose of creating the three-dimensional structure.

Preferably, the lithographic material holder is designed to hold the lithographic material in position for creating the three-dimensional structure. The lithographic material holder can be referred to as a lithographic material carrier.

Various geometric designs are conceivable for the lithographic material holder, each of which can bring different advantages. The lithographic material holder can be designed, for example, as a tub, container or pot for holding the lithographic material. It is also conceivable for the lithographic material holder to be designed as a table or carrier or substrate on which the lithographic material lies in droplet or layer form. For the creation of the three-dimensional structure on the substrate it is also conceivable for a substrate, in particular in the form of a wafer, to be placed on the table, and for the lithographic material to lie on the substrate in drop-like or layered form. The table can be a machine table of a lithography device.

The lithographic material holder can be designed to be transparent to the laser writing beams, at least in regions. For example, walls or floors or cover plates of the lithographic material holder, if present in the specific design, can be designed to be transparent to the laser writing beams. The laser writing beams can thus be focused through the lithographic material holder and into the lithographic material. For example, irradiation or exposure of the lithographic material from below can be made possible.

The input laser beam can be a continuous wave laser beam or a pulsed laser beam. In particular, a laser pulse of the pulsed laser beam can have a pulse duration of 50 femtoseconds to 500 nanoseconds.

The demultiplexing of the input laser beam can be a temporal and/or spatial demultiplexing of the input laser beam. In particular, the temporal and spatial demultiplexing of the input laser beam can be effected simultaneously. Preferably, demultiplexing the input laser beam can result in temporal and spatial splitting of the input laser beam. Splitting can be understood as deflecting, directing, decoupling or extracting. The splitting can be effected by means of an optical switch. The optical switch can be a fiber-integrated optical switch.

In this respect, the method provides in particular forming a plurality of laser writing beams by demultiplexing the laser beam by means of a demultiplexer unit which is arranged between the laser beam source and an objective. Demultiplexing is in particular the opposite of multiplexing. Demultiplexing can include directing or guiding at least part of the power of the input laser beam to one of several outputs of the demultiplexer unit. At least part of the power of the input laser beam directed or guided toward the output can form a laser writing beam after passing through the output. The demultiplexing can comprise alternately directing or guiding at least parts of the power of the input laser beam to outputs of the demultiplexer unit that are different from each other.

If the input laser beam is a pulsed laser beam, demultiplexing can be pulse picking of individual laser pulses or laser pulse groups of the pulsed input laser beam. If the input laser beam is a continuous wave laser beam, the demultiplexing can be the forming of pulsed laser writing beams, wherein in particular a pulse width and/or a pulse length is equal to a switching duration of the demultiplexer unit. For example, duty cycle pulses can be generated by the demultiplexer unit. In other words, a continuous wave laser beam can be pulsed using the demultiplexer unit.

The demultiplexing of the input laser beam can be carried out constantly over time, periodically or depending on a signal. For example, demultiplexing can be performed such that each laser writing beam is formed from the input laser beam for a specified period of time. The specified time period can be, for example, 100 femtoseconds to 500 nanoseconds.

Each laser writing beam can propagate along a beam axis. The beam axes of the laser writing beams can differ from each other. The beam axes of the laser writing beams can be oriented parallel to and offset from each other. The beam axes of the laser writing beams and a beam axis of the input laser beam can differ from each other; in particular, the beam axis of the input laser beam can be oriented orthogonally to the beam axes of the laser writing beams. In other words, the beam axes of the laser writing beams cannot run collinearly with the beam axis of the laser beam.

The beam axis can be understood as a longitudinal axis of the particular laser beam which extends in the direction of its propagation. In this respect, the beam axis can be defined by the Poynting vector of the radiation. The Poynting vector can be an effective Poynting vector. The effective Poynting vector can, for example, be an intensity-weighted, averaged Poynting vector.

Each laser writing beam can be designed to transfer the lithographic material into an exposed state by means of two- or multi-photon polymerization, in particular to polymerize or to solidify it in another way.

Focusing the plurality of laser writing beams can include forming a plurality of foci. In particular, all laser writing beams are focused using the same objective, in particular in such a way that each laser writing beam has its own, assigned focus. The foci can be separate from each other spatially and temporally. In other words, the plurality of laser writing beams can be focused in such a way that the laser writing beams form a focus one after the other in time and next to each other in space. Preferably, the arrangement is such that the foci lie within a volume of lithographic material, preferably below the surface of the lithographic material.

In connection with the step of focusing the plurality of laser writing beams, in particular before focusing, the method can comprise the step of immersing the objective in the lithographic material. In other words, the method can be a dip-in multi-photon polymerization method.

The objective can, for example, have a numerical aperture in the range from 0.01 up to and including 1.6. In particular, high numerical apertures can contribute to high precision.

Creating the three-dimensional structure in the lithographic material can comprise spatially superimposing the foci of the laser writing beams with the lithographic material. In other words, the laser writing beams are focused into the lithographic material for the purpose of creating the three-dimensional structure. The three-dimensional structure in the lithographic material can be created using multi-photon polymerization of the lithographic material.

In a further development of the method, the demultiplexing comprises forming each laser writing beam by decoupling a portion of the laser beam from the input laser beam sufficient to transfer the lithographic material into an exposed state. In particular, decoupling can be effected in such a way that the particular laser writing beam in its focus has at least the exposure dose, energy dose and/or intensity sufficient for a two- or multi-photon polymerization of the lithographic material. Exposure can be accomplished by two- or multi-photon polymerization.

For example, the lithographic material can be liquid in an unexposed state and solid in an exposed state. In other words, by locally transferring the lithographic material into an exposed state, the lithographic material can be locally solidified. The unexposed and liquid lithographic material can then be separated from the lithographic material that has solidified as a result of exposure, e.g. in the context of a development step.

In an alternative example, the lithographic material can be solid in an unexposed state and, in an exposed state, its structure, e.g. chemical structure, molecular structure, cross-linking of the lithographic material, degree of polymerization or the like, can be changed compared to the unexposed state. In other words, the lithographic material can be locally transferred into an exposed state by changing the cross-linking of the lithographic material. The unexposed lithographic material can then be separated from the exposed lithographic material, e.g. in a development step.

In a further development of the method, the input laser beam is a pulsed laser beam which has a plurality of laser pulses. The plurality of laser writing beams is formed by decoupling a first group of laser pulses and at least a second group of laser pulses from the pulsed input laser beam. The first group of laser pulses forms a first laser writing beam, and the second group of laser pulses forms a second laser writing beam. The first group of laser pulses and the second group of laser pulses can be separated from each other in time and space. The decoupling can be referred to as pulse picking.

In a further development of the method, the method comprises the step of detecting a power of the input laser beam in the beam path of the input laser beam after demultiplexing. The formation of the plurality of laser writing beams occurs as a function of the detected power. Detecting the power can be detecting the power of a residual beam of the input laser beam. The residual beam is preferably not a laser writing beam. In particular, the residual beam can be a laser beam that remains from the input laser beam after the demultiplexing of the input laser beam. Demultiplexing can be performed by means of a demultiplexer unit. The power can be detected downstream of the demultiplexer unit. The power can be a power of the input laser beam after passing through the demultiplexer unit.

In a further development of the method, the method has the step of coupling the plurality of laser writing beams into a waveguide arrangement that has a plurality of waveguides. In each case one waveguide is assigned to a laser writing beam. The waveguides are arranged in the beam path between the laser beam source and the objective. By means of the waveguide arrangement, the method can be advantageously carried out in a particularly stable and reliable manner. The waveguide arrangement can produce a defined spatial arrangement of the laser writing beams relative to each other and maintain this robustly against interferences. Each waveguide can be designed to guide or direct the particular laser writing beam. Each waveguide can be designed as a hollow-core fiber or a solid-core fiber or include one.

In a further development of the method, each waveguide has a first end and a second end opposite the first end. Each first end is configured to couple-in a laser writing beam, and each second end is configured to decouple the laser writing beam coupled into the first end. The second ends of the plurality of waveguides are held by a holding matrix of the waveguide arrangement. The method can provide for a shifting of the foci relative to the lithographic material holder by means of a shifting of the holding matrix. The waveguides can, if necessary, follow the movement of the holding matrix, for example by corresponding (elastic) deformation, bending or similar. The shifting of the foci relative to the lithographic material holder can also be carried out or supported by a shifting of the objective. Alternatively or in addition to the aforementioned options, the foci can be shifted relative to the lithographic material holder by shifting the lithographic material holder and/or shifting the foci relative to the lithographic material holder using an optical deflection apparatus by deflecting the laser writing beams.

The provision of the holding matrix enables a particularly compact and precise holding of the second ends of the waveguides relative to one another in a defined arrangement.

The holding matrix can be formed from plastic, resin, glass or silicon in which the second ends of the waveguides are at least partially, in particular sectionally, embedded.

The holding matrix can have a substrate with precision-machined V-shaped notches for insertion of the waveguides. Alternatively, the holding matrix can have a microstructured perforated plate, wherein the waveguides can be inserted into holes in the perforated plate. Alternatively, the holding matrix can have a plurality of ferrules, wherein the waveguides can be inserted into the ferrules. Alternatively, the holding matrix can be a welded connection between the second ends of the waveguides of the waveguide arrangement.

Shifting can be understood as the performance of a movement. Each shift can be carried out by means of a drive, in particular a linear drive and/or a rotary drive.

The shifting of the holding matrix can be carried out by means of a movement of the holding matrix transverse to the laser writing beams and/or a movement of the holding matrix longitudinal in relation to the laser writing beams.

During the shifting of the foci relative to the lithographic material holder by means of shifting the holding matrix, the objective can be stationary or can be shifted together with the holding matrix. A shifting of the holding matrix together with the objective can mean that the holding matrix and the objective are shifted simultaneously in the same direction and by the same distance. The joint shifting of the holding matrix and the objective can be achieved, for example, by means of the same drive.

During the shifting of the foci relative to the lithographic material holder by means of a shift of the lithographic material holder, the holding matrix and/or the objective can be stationary.

The optical deflection apparatus can be arranged between the waveguide arrangement and the objective. The optical deflection apparatus can have a scanner mirror, a mirror galvanometer, an acousto-optic deflector, an acousto-optic modulator and/or a pellicle mirror for deflecting the laser writing beams.

In a further development of the method, each waveguide is designed as a hollow-core optical fiber. This ensures that unwanted absorption is significantly reduced and that the damage threshold of the waveguide is considerably higher. Furthermore, each hollow-core fiber can be matched with its associated laser writing beam in such a way that no pulse broadening of a laser pulse of the laser writing beam occurs after passage through the hollow-core fiber. The hollow-core fiber can be an optical fiber that has a hollow fiber core.

In a further development of the method, each waveguide is selected from the group comprising: HC PCF fibers, in particular HC kagome fibers, HC PBGF fibers, HC ARF fibers, HC IC fibers, RH fibers, LMA fibers, PCF fibers.

HC PCF fibers can be understood to be hollow-core photonic crystal fibers, HC kagome fibers to be hollow-core kagome fibers, HC PBGF fibers to be hollow-core photonic bandgap fibers, HC ARF fibers to be hollow-core anti-resonant fibers, HC IC fibers to be hollow-core inhibited coupling fibers, RH fibers to be radiation-hardened fibers, LMA fibers to be large mode area fibers, PCF fibers to be photonic crystal fibers.

A laser lithography device according to this disclosure for producing a three-dimensional structure in a lithographic material. Insofar as features and components of the laser lithography device are also described in connection with the method, the statements in that regard also apply accordingly to the laser lithography device. The device has a lithographic material holder, a laser beam source, a demultiplexer unit, an objective and a scanning apparatus. The lithographic material holder is designed to hold the lithographic material. The laser beam source is designed to create an input laser beam. The demultiplexer unit is arranged between the laser beam source and the objective, in particular in the propagation direction of the input laser beam. The demultiplexer unit is configured to split the input laser beam over time into a plurality of laser writing beams by demultiplexing. The objective is designed to focus the laser writing beams in a focus assigned to each laser writing beam. The scanning apparatus is designed to shift the foci relative to the lithographic material holder.

The laser lithography device is in particular designed and specifically configured to carry out a method described above. The above description of the method can also apply to identical or functionally equivalent features of the laser lithography device.

The scanning apparatus can have a previously described optical deflection apparatus for shifting the foci relative to the lithographic material holder by deflecting the laser writing beams. The optical deflection apparatus of the scanning apparatus can be arranged between the demultiplexer unit and the objective.

Additionally or alternatively, the scanning apparatus can be designed to shift the foci relative to the lithographic material holder by means of a shift of the objective and/or to shift the foci relative to the lithographic material holder by means of a shift of the lithographic material holder. For the shifting, the scanning apparatus can here comprise actuators, in particular servomotors or linear actuators, preferably vibrating piezo-actuators.

Lithographic material can be held by the lithographic material holder. The lithography device can also comprise the lithographic material.

In a further development of the laser lithography device, the laser beam source is designed to create a pulsed input laser beam that has a plurality of laser pulses. The demultiplexer unit is designed such that the demultiplexing is carried out by decoupling a first group of laser pulses and at least a second group of laser pulses from the pulsed input laser beam. The first group of laser pulses forms a first laser writing beam, and the second group of laser pulses forms a second laser writing beam.

In a further development of the laser lithography device, the demultiplexer unit has a plurality of, in particular three, four or five, optical switches which are arranged in a series one after the other in the beam path of the input laser beam. Each optical switch is configured in a switched position to form a respective laser writing beam by decoupling from the input laser beam a portion of the laser beam sufficient to transfer the lithographic material into an exposed state. In an unswitched position, in particular, a laser writing beam is not decoupled. Each optical switch can be designed as a fiber-integrated optical switch.

The optical switches can be arranged in series in the direction of propagation of the input laser beam. The plurality of optical switches can be equal to the plurality of laser writing beams. In each case one optical switch each can be provided for forming a laser writing beam.

Each optical switch can have an acousto-optic modulator or an acousto-optic deflector for decoupling a portion of a laser beam from the input laser beam sufficient to transfer the lithographic material into an exposed state. Each optical switch can have a digital input to for transferring the optical switch into the switched position. A signal can be applied to the digital input to move the optical switch between the switched position and an unswitched position. For example, the optical switch can be in the switched position when the signal is applied to the digital input and in the unswitched position when no signal is applied to the digital input.

When the optical switch is in the unswitched position, it is in particular provided that the input laser beam can pass through the optical switch without forming a laser writing beam.

It is conceivable that the degree to which each optical switch is decoupled is adjustable, in particular infinitely variable. The degree to which an optical switch is decoupled can be a relationship of the power, in particular a peak power or an average power, of the laser writing beam formed with the optical switch relative to a power, in particular a peak power or an average power, of the input laser beam upstream of the optical switch. In the unswitched position, the degree of decoupling can be 0%. In other words, at a degree of decoupling of 0%, the input laser beam can pass through the optical switch without forming a laser writing beam. In the switched position, the degree of decoupling can be, for example, 10%, 20%, 30%, 40%, 50%, 60%, 80%, 90% or 95%. In other words, a power of the laser writing beam formed by the optical switch is 10%, 20%, 30%, 40%, 50%, 60%, 80%, 90% or 95% of the power of the input laser beam upstream of the optical switch when the latter is continuously in the switched position.

The optical switch can have an analog input to which a signal can be applied in order to adjust the degree of decoupling. By adjusting the degree of decoupling, different exposure levels of the lithographic material can be achieved.

In a further development of the laser lithography device, the demultiplexer unit has an optical switch which is arranged in the beam path of the input laser beam downstream of the laser beam source. The demultiplexer unit has an optical arrangement which is configured to guide the input laser beam several times through the optical switch. In a switched position, the optical switch is configured to form from the input laser beam a laser writing beam by decoupling a portion of the laser beam sufficient to transfer the lithographic material into an exposed state.

The demultiplexer unit can in particular have a single optical switch. The optical arrangement can then be configured to pass the input laser beam via the optical switch twice, three times or four times. The optical arrangement can be configured to guide the input laser beam multiple times at different angles of incidence via the optical switch. The above description of an optical switch can also apply to the optical switch through which the input laser beam is routed several times.

In a further development of the laser lithography device, the laser lithography device has a power detection unit for detecting a power of the input laser beam in the beam path after the demultiplexer unit. The laser lithography device has a control unit that is configured to control the demultiplexer unit for the purpose of forming the plurality of laser writing beams by demultiplexing the input laser beam as a function of the detected power. The control unit can be a computer or a computing unit.

The power detection unit can be a photodiode or a power detector for detecting the power of the input laser beam. The power detection unit can be arranged such that the power detection unit detects a power of a residual beam of the input laser beam. The residual beam cannot be a laser writing beam. The residual beam can be a laser beam that remains from the input laser beam after passage through the demultiplexer unit. The power can be a power of the residual beam.

In a further development of the laser lithography device, the laser lithography device has a waveguide arrangement which has a plurality of waveguides for guiding the plurality of laser writing beams. In each case one waveguide is assigned to a laser writing beam. The waveguides in the beam path are arranged between the demultiplexer unit and the objective. Each waveguide has a first end and a second end opposite the first end. Each first end is configured to couple-in a laser writing beam, and each second end is configured to decouple the laser writing beam coupled into the first end. The second ends of the plurality of waveguides are held by a holding matrix of the waveguide arrangement. Within the holding matrix, the waveguides can run parallel to and offset from each other. Each waveguide can be formed as a hollow-core fiber or as a solid-core fiber, or can comprise a corresponding fiber.

The second ends can be spaced apart from one another in the propagation direction of the laser writing beams coupled out of the second ends. In other words, each second end of the plurality of waveguides can have an end face that is configured to decouple the laser writing beam coupled into the first end, wherein the end faces of the second ends are arranged in planes different from one another. In other words, the second ends extend to different distances. Advantageously, this enables simultaneous exposure of the lithographic material in different planes. This can increase the stability of the three-dimensional structure during creation or the printing process. In addition, the three-dimensional structure can be created more quickly. In particular, this can make possible a realization of a higher packing density of the foci.

In a further development of the laser lithography device, the second ends of the plurality of waveguides are held by the holding matrix in a linear arrangement or in a two-dimensional arrangement. The linear arrangement and/or the two-dimensional arrangement can be a regular arrangement.

If the second ends are held in the linear arrangement, the second ends can be equidistant from each other. If the second ends are held in the two-dimensional arrangement, the second ends can be arranged in a crystal-like structure. Crystal-like structure can be understood to mean that the second ends are arranged like a dot lattice with a periodic, repeating pattern.

In a further development of the laser lithography device, the distance between two adjacent second ends of the plurality of waveguides is 25 μm to 1000 μm, in particular 115 μm to 600 μm. This achieves a particularly compact waveguide arrangement.

In a further development of the laser lithography device, every second end of the plurality of waveguides has an end face which is configured to decouple the laser writing beam coupled into the first end. The end faces of the second ends are arranged in one plane. The plane can be aligned perpendicular to a propagation direction of the coupled-out laser writing beams.

In a further development of the laser lithography device, the scanning apparatus is configured to shift the foci relative to the lithographic material holder by means of a shift of the holding matrix. For this purpose, the scanning apparatus can comprise actuators, in particular servomotors or linear motors which shift the holding matrix.

In a further development of the laser lithography device, each waveguide is designed as a hollow-core optical fiber.

In a further development of the laser lithography device, each waveguide is selected from the group comprising: HC PCF fibers, in particular HC kagome fibers, HC PBGF fibers, HC ARF fibers, HC IC fibers, RH fibers, LMA fibers, PCF fibers.

### BRIEF DESCRIPTION OF THE DRAWINGS

Further advantages and aspects of this disclosure emerge from the claims and from the following description of preferred exemplary embodiments of this disclosure, which are explained below with reference to the figures. Identical and functionally corresponding elements are provided with identical reference signs. In the figures:

FIG. 1 shows a schematic view of a laser lithography device,

FIG. 2 shows a schematic representation of an operation of a demultiplexer unit of the laser lithography device,

FIG. 3 shows a schematic view of a front side of a waveguide arrangement of the laser lithography device,

FIG. 4 shows a schematic view of FIG. 3 for a variant of the waveguide arrangement,

FIG. 5 shows a schematic representation of foci of the laser writing beams in a focal plane,

FIG. 6 shows a schematic representation of the foci of FIG. 5 in a plane orthogonal to the focal plane, and

FIG. 7 shows a schematic view of FIG. 1 for a variant of the laser lithography device.

### DETAILED DESCRIPTION

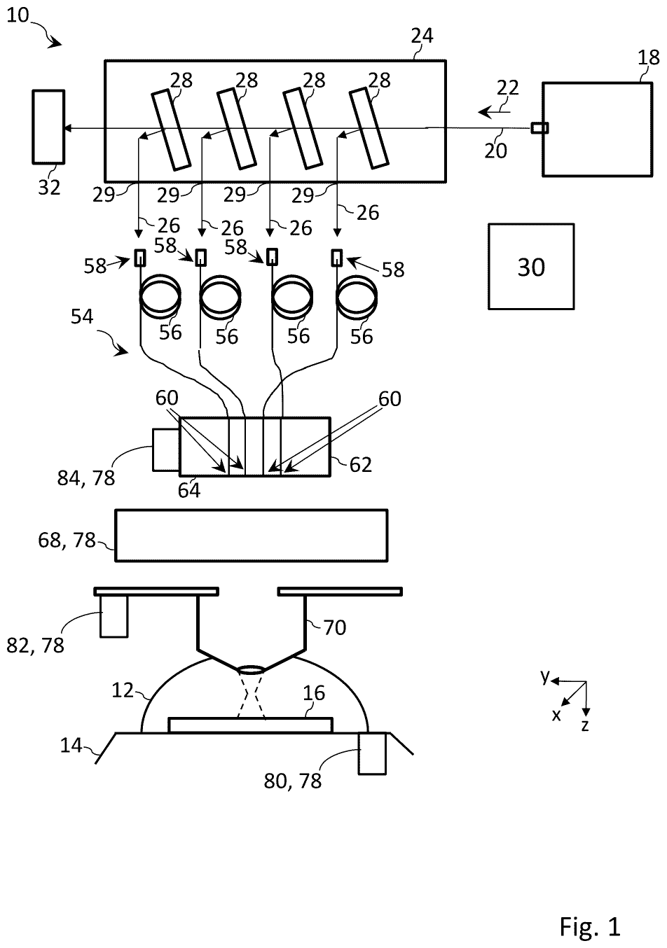

FIG. 1 shows a laser lithography device 10 for creating a three-dimensional structure in a lithographic material 12 by means of multi-photon polymerization.

The laser lithography device 10 has a lithographic material holder 14. The lithographic material holder 14 is designed as a table in the form of a machine table. A substrate 16 in the form of a wafer is placed on the lithographic material holder 14, on which the three-dimensional structure is to be created.

The lithographic material 12 lies in droplet form on the lithographic material holder 14 and on the substrate 16. FIG. 1 shows that the lithographic material 12 contacts the lithographic material holder 14 and the substrate 16. In an alternative embodiment (not shown), the lithographic material only contacts the substrate. In both cases, the lithographic material holder 14 is designed to hold the lithographic material 12 for the purpose of creating the three-dimensional structure.

The laser lithography device 10 has a laser beam source 18 for generating an input laser beam 20. The input laser beam 20 propagates in a propagation direction 22.

The input laser beam 20 is a pulsed laser beam that comprises a plurality of laser pulses. A laser pulse of the pulsed input laser beam 20 has a pulse duration of 250 femtoseconds. The laser pulses of the pulsed input laser beam 20 have a repetition rate of 80 MHz.

The laser lithography device 10 has a demultiplexer unit 24. The demultiplexer unit 24 is arranged in the propagation direction 22 of the input laser beam 20 after the laser beam source 18. The demultiplexer unit 24 is configured to split the input laser beam 20 temporally and spatially into a plurality of laser writing beams 26 by demultiplexing.

Each laser writing beam 26 propagates along a beam axis. The beam axis is a longitudinal axis of the particular laser writing beam 26, which extends in the direction of its propagation. The beam axes of the laser writing beams 26 differ from each other. The beam axes of the laser writing beams 26 are oriented parallel to and offset from each other. The beam axes of the laser writing beams 26 and a beam axis of the input laser beam 20 are oriented orthogonally to each other. In other words, the beam axes of the laser writing beams 26 do not run collinearly with the beam axis of the laser beam 20.

In the example shown in FIG. 1, the input laser beam 20 is split by the demultiplexer unit 24 into a total of four laser writing beams 26. For this purpose, the demultiplexer unit 24 has a total of four optical switches 28 which are arranged one after the other in series in the propagation direction 22. In other words, in an unswitched position of the optical switches 28, the input laser beam 20 can pass through the optical switches 28 one after the other without being influenced by them.

In each case one optical switch 28 is provided for forming a laser writing beam 26. Each optical switch 28 is configured in a switched position to form a respective laser writing beam 26 from the input laser beam 20. Each optical switch 28 is designed as an acousto-optic modulator. The laser writing beams 26 are formed by decoupling a portion of the laser beam from the input laser beam 20 sufficient to solidify the lithographic material 12. In other words, demultiplexing is directing or guiding the sufficient portion of the laser beam to one of several outputs 29 of the demultiplexer unit 24. In the illustrated exemplary embodiment, this is effected by means of the optical switches 28 and deflection mirrors (not shown for the sake of simplicity).

In total, the demultiplexer unit 24 has four outputs 29. The number of outputs 29 is equal to the number of laser writing beams 26 that are formed by the demultiplexer unit 24. A sufficient portion of the laser beam directed or guided to an output 29 forms a laser writing beam 26 after passage through the output 26.

In order to form the four laser writing beams 26 by means of the demultiplexer unit 24, an optical switch 28 is successively transferred into the switched position, which then decouples a sufficient portion of the laser beam from the input laser beam 20 and directs it to the associated output 29.

Each optical switch 28 has a digital input for transferring the optical switch between the unswitched position and the switched position. The transfer to the switched position or to the unswitched position is carried out by means of a signal that is applied to the digital input. In the example illustrated, the optical switch 28 is in the switched position when a signal is applied to the digital input and in the unswitched position when a signal is not applied to the digital input.

The laser lithography device 10 has a control unit 30 which is configured to control the demultiplexer unit 24 for the purpose of forming the laser writing beams 26 by demultiplexing the input laser beam 20. The optical switches 28 are successively transferred into the switched position by the control unit 30. For this purpose, the control unit 30 applies a signal to the digital inputs of the individual optical switches 28 one after the other.

The laser lithography device 10 has a power detection unit 32 in the form of a power detector for detecting a power of the input laser beam 20 downstream of the demultiplexer unit 24. The power detection unit 32 thus detects the power of the input laser beam 20 that is left over from the input laser beam 20 after passage through the demultiplexer unit 24. In the example shown in FIG. 1, the power detection unit 32 is arranged such that when the optical switches 28 are in the unswitched position and the input laser beam 20 passes through the optical switches 28 one after the other without being influenced by them, the input laser beam 20 strikes the power detection unit 32. The power detection unit 32 detects a power of the input laser beam 20 which is equal to a power of the input laser beam 20 upstream of the demultiplexer unit 24.

If one of the optical switches 28 is in the switched position and, for example, 80% of the peak power of the input laser beam 20 is decoupled to form a laser writing beam 26, the power detection unit 32 will detect a power of the input laser beam 20, wherein the peak power of the input laser beam 20 striking the power detection unit 32 is 20% of the peak power of the input laser beam 20 upstream of the demultiplexer unit 24.

The control unit 30 is configured to control the demultiplexer unit 24 as a function of the power detected by the power detection unit 32.

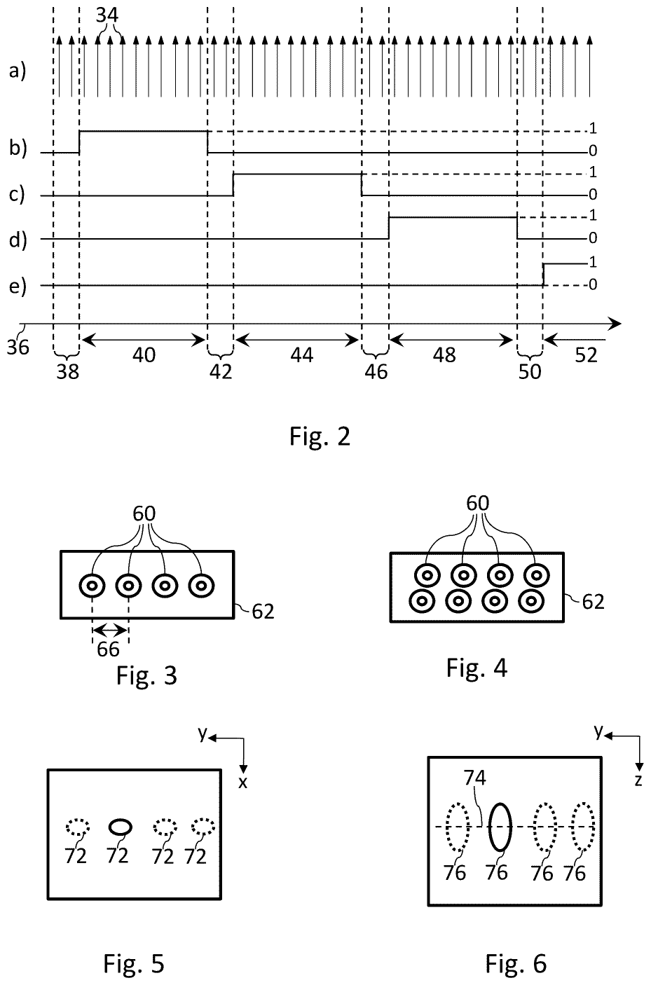

An example of operation of the demultiplexer unit 24 is shown in FIG. 2.

In FIG. 2 a), individual laser pulses 34 of the pulsed input laser beam 20 upstream of the demultiplexer unit 24 are shown in the form of arrows over a time axis 36. In FIG. 2 b) to e), a temporal progression of a signal which the control unit 30 applies to the digital input of the respective optical switch 28 is shown over the time axis 36. When the signal has the value 1, the respective optical switch 28 assumes the switched position, and when the signal has the value 0, the respective optical switch 28 assumes the unswitched position.

The control unit 30 is configured to apply signals to the digital inputs of the optical switches 28 one after the other for a specified duration. The specified duration is the same for all optical switches 28. In the exemplary embodiment in FIG. 2, the specified duration is selected such that each optical switch 28 decouples ten laser pulses 34 from the input laser beam 20. In other words, the control unit 30 is configured to apply signals for a duration of ten laser pulses 34 to the digital inputs of the optical switches 28. However, the specified duration can also be chosen to be different so that more or fewer laser pulses 34 are decoupled. The decoupled laser pulses 34 at least partially form the laser writing beams 26.

Between two signals successively applied to the optical switches 28, no signal is applied to the optical switch 28 for a specified period of time. In the exemplary embodiment in FIG. 2, the specified time period is selected such that, between the decoupled laser pulses 34, two laser pulses 34 are not decoupled by the optical switches 28. The laser pulses 34 which are not decoupled reach the power detection unit 32. However, the specified time period can also be selected to be different so that more or fewer laser pulses reach the power detection unit 32.

In detail, FIG. 2 shows that two laser pulses 34 of a time period 38 reach the power detection unit 32. The control unit 30 applies the signal shown in FIG. 2 b) to a first optical switch 28 for a time period 40 which includes ten laser pulses 34. The ten laser pulses 34 decoupled by means of the first optical switch 28 at least partially form a first laser writing beam 26. Subsequently, two laser pulses 34 of a time period 42 reach the power detection unit 32. The control unit 30 applies the signal shown in FIG. 2 c) to a second optical switch 28 for a time period 44 which includes ten laser pulses 34. The ten laser pulses 34 decoupled by means of the second optical switch 28 at least partially form a second laser writing beam 26. The two laser pulses 34 of a time period 46 then reach the power detection unit 32. The control unit 30 applies the signal shown in FIG. 2 d) to a third optical switch 28 for a time period 48 which includes ten laser pulses 34. The ten laser pulses 34 decoupled by means of the third optical switch 28 form at least partially a third laser writing beam 26. The two laser pulses 34 of the time period 50 then reach the power detection unit 32. The control unit 30 applies the signal shown in FIG. 2 e) to a fourth optical switch 28 for a time period 52 which includes ten laser pulses 34. The ten laser pulses 34 decoupled by means of the fourth optical switch 28 form at least partially a fourth laser writing beam 26. With the following two laser pulses 34, the sequence of applying the signal to the optical switches 28 starts again.

Calibration of the optical switches 28, in particular calibration of the temporal offsets for operation of the optical switches 28, is carried out by applying one periodic signal in each case to two optical switches 28, whereas no signal is applied to the remaining optical switches 28. After this, a temporal offset between the two periodic signals is changed, and at the same time, the average power is detected by means of the power detection unit 32. In this case, a maximum average power is detected in the power detection unit 32 when the two optical switches 28 are simultaneously in the switched position. The temporal offset of this state can be used to determine the temporal offset at which the operating state shown in FIG. 2 occurs for these two optical switches 28. The remaining optical switches 28 are calibrated correspondingly.

The demultiplexer unit 24 is designed such that demultiplexing is carried out by decoupling groups of laser pulses from the pulsed input laser beam 20. The groups of laser pulses form the laser writing beams 26. In other words, the demultiplexer unit 24 forms the laser writing beam 26 by pulse picking. The laser writing beams 26 are formed by temporally and spatially splitting the laser pulses 34 of the input laser beam 20.

The optical switches 28 in each case have an analog input to which a signal can be applied in order to set a degree of decoupling. The degree of decoupling of each optical switch 28 is adjustable infinitely variably. The degree of decoupling is a relationship of the peak power of a laser writing beam 26 formed with an optical switch 28 relative to a peak power of the input laser beam 20 upstream of the optical switch 28.

The control unit 30 is configured to apply to the respective optical switch 28 a signal for adjusting the degree of decoupling. In the example illustrated, the control unit 30 applies a signal to the analog input such that the degree of decoupling is 80%. In other words, a peak power of the laser pulses decoupled by the optical switches 28 is reduced by 20% compared to the peak power of the laser pulses of the input laser beam 20.

The laser lithography device 10 has a waveguide arrangement 54; see FIG. 1. The waveguide arrangement 54 has a plurality of waveguides 56 for guiding the plurality of laser writing beams 26. In each case one waveguide 56 is assigned to a laser writing beam 26.

The waveguides 56 are arranged in the beam path downstream of the demultiplexer unit 24. Each waveguide 56 is a hollow-core optical fiber, namely a hollow-core photonic crystal fiber. Each waveguide 56 is designed to direct or guide the laser writing beam 26 associated with the waveguide 56.

Each waveguide 56 has a first end 58 and a second end 60 opposite the first end. Each first end 58 is configured to couple-in the laser writing beam 26 associated with the waveguide 56. The laser writing beams 26 are coupled into the waveguides 56 via free-space beam coupling. Each second end 60 has an end face that is configured to decouple the laser writing beam 26 coupled into the first end 58. Each second end 60 is thus configured to decouple the laser writing beam 26 coupled into the first end 58.

The second ends 60 are held by a holding matrix 62 of the waveguide arrangement 54. Within the holding matrix 62, the waveguides 56 run parallel to and offset from one another. In the example illustrated, the holding matrix 62 has a substrate with precision-machined, parallel V-shaped notches. The substrate can be made of plastic, resin, glass or silicon, for example. The waveguides 56 are inserted into the notches. Free spaces between the waveguides 56 and the substrate are filled with adhesive suitable for optics, for example in the form of UV adhesive. A cover of the holding matrix 62 is glued on, which presses the waveguides 56 into the V-shaped notches.

The end faces of the second ends 60 are arranged in one plane. The plane and the end faces 64 are aligned perpendicular to a propagation direction of the coupled-out laser writing beams 26.

FIG. 3 shows a schematic representation of the end face 64 of the waveguide arrangement 54. The second ends 60 of the waveguides 56 are held by the holding matrix 62 in a regular linear arrangement. In other words, the second ends 60 have the same distance 66 from each other. The distance 66 between two adjacent second ends 60 is 250 μm.

FIG. 4 shows another exemplary embodiment of the waveguide arrangement 54 of FIG. 3, which is suitable for use with up to eight laser writing beams. The same reference signs are used for identical and functionally equivalent elements, and in this respect, reference can be made to the above explanations regarding the exemplary embodiment of FIG. 3 so that basically only the existing differences will be addressed.

The second ends 60 of the waveguide arrangement 54 of FIG. 4 are held by the holding matrix 62 in a regular two-dimensional arrangement. The second ends 60 are arranged like a crystal structure. In other words, the second ends 60 are arranged in a periodic, repeating pattern.

FIG. 1 shows that the lithography device 10 has an optical deflection apparatus 68 in the form of a mirror galvanometer and an objective 70 in the beam path of the laser writing beams 26 downstream of the waveguide arrangement 54. The optical deflection apparatus 68 is designed to deflect the laser writing beams 26, and the objective 70 is designed to focus the laser writing beams 26.

The objective 70 is immersed in the lithographic material 12. The objective 70 focuses the laser writing beams 26 for the purpose of creating the three-dimensional structure in the lithographic material 12. The foci of the laser writing beams 26 all lie in one focal plane.

FIG. 5 is a schematic representation of a view of the focal plane and the individual foci 72. By demultiplexing the input laser beam 20, the foci 72 are formed within the lithographic material 12, separated from one another in time and space. This is illustrated in FIG. 5 by the dashed and solid representations of the foci 72.

FIG. 6 is a schematic representation of the foci 72 of FIG. 5 in a plane orthogonal to the focal plane 74. Shown are areas 76 around the foci of the laser writing beams in which the lithographic material 12 solidifies by means of multi-photon polymerization. The laser writing beams 26 formed by the demultiplexing thus have a portion of the laser beam from the input laser beam 20 sufficient to solidify the lithographic material 12.

FIG. 1 shows that the lithography device 10 has a scanning apparatus 78 for shifting the foci 72 relative to the lithographic material holder 14. The scanning apparatus 78 comprises the optical deflection apparatus 68. In addition, the scanning apparatus 78 has an actuator 80 which is arranged on the lithographic material holder 14, an actuator 82 which is arranged on the objective 70, and an actuator 84 which is arranged on the holding matrix 62. Each actuator 80, 82, 84 is a linear actuator in the form of a piezo-actuator. In an alternative embodiment (not shown), other actuator types are also conceivable.

In an alternative exemplary embodiment (not shown), the lithography device 10 can have at least one actuator of the actuators 80, 82, 84.

By means of the actuator 80 arranged on the lithographic material holder 14, the scanning apparatus 78 can shift the foci 72 relative to the lithographic material holder 14 by shifting the lithographic material holder 14. By means of the actuator 82 arranged on the objective 70, the scanning apparatus 78 can shift the foci 72 relative to the lithographic material holder 14 by shifting the objective 70. By means of the actuator 84 arranged on the holding matrix 62, the scanning apparatus 78 can shift the foci 72 relative to the lithographic material holder 14 by shifting the holding matrix 62. By means of the optical deflection apparatus 68, the scanning apparatus 78 can shift the foci 72 relative to the lithographic material holder 14 by shifting the laser writing beams 26.

The laser lithography device 10 is designed to carry out a method to create a three-dimensional structure in the lithographic material 12. The method comprises the steps of: holding the lithographic material 12 using the lithographic material holder 14; generating the input laser beam 20 by means of the laser beam source 18; forming four laser writing beams 26 by demultiplexing the input laser beam 20 by means of a demultiplexer unit 62 which is arranged between the laser beam source 18 and the objective 70; coupling-in the plurality of laser writing beams 26 into a waveguide arrangement 54 that has a plurality of waveguides 56; immersing the objective into the lithographic material; focusing the plurality of laser writing beams 26 into the lithographic material 12 by means of the objective 70; creating the three-dimensional structure in the lithographic material 12 by means of the focused laser writing beams 26 by multi-photon polymerization.

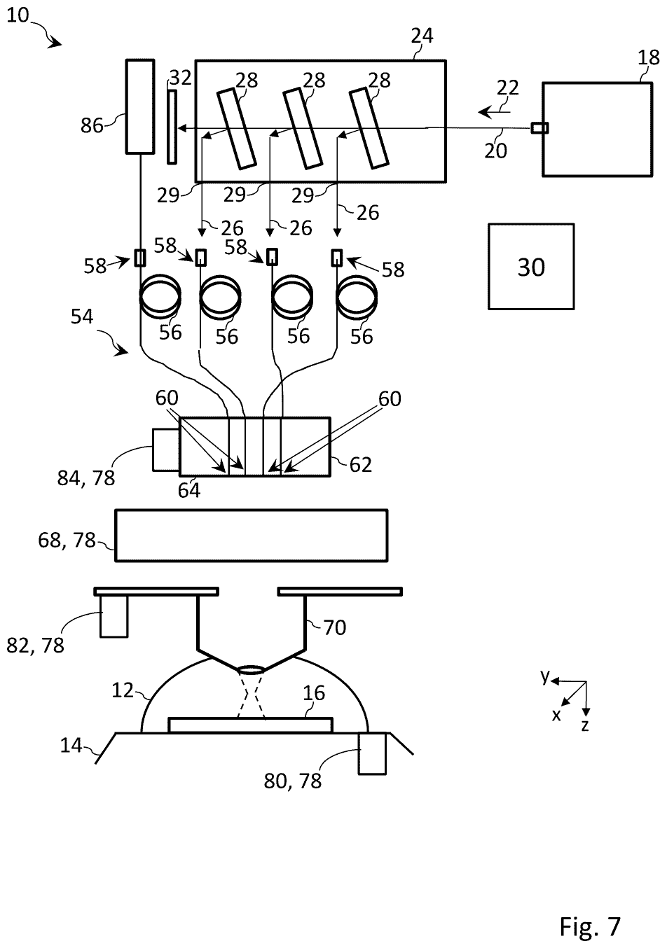

FIG. 7 shows a further exemplary embodiment of the laser lithography device 10 of FIG. 1, wherein the same reference signs are used for identical and functionally equivalent elements and, in this respect, reference can be made to the above explanations regarding the exemplary embodiment of FIG. 1 so that basically only the existing differences will be discussed.

The laser lithography device 10 has an additional laser beam source 86. The additional laser beam source 86 is designed to create a continuous wave laser beam.

In an alternative exemplary embodiment (not shown), the additional laser beam source can be designed to create a pulsed laser beam.

In the exemplary embodiment in FIG. 7, the additional laser beam source 86 is coupled to a waveguide 56 of the waveguide arrangement 54. In other words, the additional laser beam source 86 provides its created laser beam at a fiber output which is coupled to the first end of a waveguide 56 of the waveguide arrangement 54. To couple-in the laser radiation created, the fiber output can be spliced to the first end of the waveguide 56. Alternatively, the fiber output and the first end of the waveguide 56 can be held by a coupler for the purpose of coupling-in the created laser radiation into the first end.

The additional laser beam source 86 can have integrated power modulation. The integrated power modulation can be implemented, for example, by means of an integrated acousto-optic modulator. Alternatively, the additional power beam source 86 can be modulated in its power by electrical switching, for example by being alternately switched on and off. Alternatively, the additional power beam source 86 can be modulated by direct modulation, for example by electrically switching the supply current.

The demultiplexer unit 24 of the laser lithography device 10 of FIG. 7 has three optical switches 28, each of which creates a laser writing beam 26 by demultiplexing the input laser beam 20. The three laser writing beams 26 are coupled into the remaining three waveguides 56 of the waveguide arrangement 54 via free-space beam coupling.

Persons skilled in the art will understand that the structures and methods specifically described herein and illustrated in the accompanying figures are non-limiting exemplary aspects, and that the description, disclosure, and figures should be construed merely as exemplary of particular aspects. It is to be understood, therefore, that this disclosure is not limited to the precise aspects described, and that various other changes and modifications may be effectuated by one skilled in the art without departing from the scope or spirit of the disclosure. Additionally, it is envisioned that the elements and features illustrated or described in connection with one exemplary aspect may be combined with the elements and features of another without departing from the scope of this disclosure, and that such modifications and variations are also intended to be included within the scope of this disclosure. Indeed, any combination of any of the disclosed elements and features is within the scope of this disclosure. Accordingly, the subject matter of this disclosure is not to be limited by what has been particularly shown and described.

What is claimed:

1. A method for creating a three-dimensional structure in a lithographic material (12), wherein the method comprises:
holding the lithographic material (12) by means of a lithographic material holder (14),
generating an input laser beam (20) by means of a laser beam source (18),
demultiplexing the input laser beam (20) to form a plurality of laser writing beams (26) by temporally splitting the input laser beam (20),
focusing the laser writing beams (26) by means of an objective (70),
creating the three-dimensional structure in the lithographic material (12) by means of the focused laser writing beams (26).

2. The method according to claim 1,
wherein each laser writing beam (26) is formed by decoupling from the input laser beam (20) a portion of the laser beam sufficient to transfer the lithographic material (12) into an exposed state.

3. The method according to claim 1,
wherein the input laser beam (20) is a pulsed laser beam that has a plurality of laser pulses (34),
wherein the input laser beam (20) is demultiplexed by decoupling a first group of laser pulses (34) and at least one second group of laser pulses (34) from the pulsed input laser beam (20) in such a way
that the first group of laser pulses (34) forms a first laser writing beam, and the second group of laser pulses (34) forms a second laser writing beam.

4. The method according to claim 1,
wherein the method comprises:
detecting a power of the input laser beam (20) in the beam path of the input laser beam (20) after demultiplexing, wherein the plurality of laser writing beams (26) are formed as a function of the detected power.

5. The method according to claim 1,
wherein the method comprises:
coupling-in the plurality of laser writing beams (26) into a waveguide arrangement (54) which comprises a plurality of waveguides (56), wherein in each case one waveguide (56) is assigned to a laser writing beam (26), and wherein the waveguides (56) are arranged in the beam path between the laser beam source (18) and the objective (70).

6. The method according to claim 5,
wherein each waveguide (56) has a first end (58) and a second end (60) opposite the first end (58),
wherein each first end (58) is configured to couple-in a laser writing beam (26), and each second end (60) is configured to decouple the laser writing beam (26) coupled into the first end (58),
wherein the second ends (60) of the plurality of waveguides (56) are held by a holding matrix (62) of the waveguide arrangement (54),
wherein the method comprises:
shifting the foci (72) relative to the lithographic material holder (14) by shifting the holding matrix (62), and/or
shifting the foci (72) relative to the lithographic material holder (14) by shifting the objective (70),
shifting the foci (72) relative to the lithographic material holder (14) by shifting the lithographic material holder (14), and/or
shifting the foci (72) relative to the lithographic material holder (14) by means of an optical deflection apparatus (68) by deflecting the laser writing beams (26).

7. The method according to claim 5,
wherein each waveguide (56) is selected from the group comprising: HC PCF fibers, in particular HC kagome fibers, HC PBGF fibers, HC ARF fibers, HC IC fibers, RH fibers, LMA fibers, PCF fibers.

8. A laser lithography device (10) for creating a three-dimensional structure in a lithographic material (12), the device comprising:
a lithographic material holder (14) for holding the lithographic material (12),
a laser beam source (18) for generating an input laser beam (20),
a demultiplexer unit (24) that is arranged between the laser beam source (18) and the objective (70),
wherein the demultiplexer unit (24) is configured to split the input laser beam (20) over time into a plurality of laser writing beams (26) by demultiplexing,
an objective (70) for focusing the laser writing beams (26) in a focus (72) assigned to the laser writing beam (26), and
a scanning apparatus (78) for shifting the foci (72) relative to the lithographic material holder (14).

9. The laser lithography device (10) according to claim 8,
wherein the laser beam source (18) is designed to create a pulsed input laser beam (20) that has a plurality of laser pulses (34),
wherein the demultiplexer unit (24) is designed such that the demultiplexing is carried out by decoupling from the pulsed input laser beam (20) a first group of laser pulses (34) and at least one second group of laser pulses (34),
wherein the first group of laser pulses (34) forms a first laser writing beam (26), and the second group of laser pulses (34) forms a second laser writing beam (26).

10. The laser lithography device (10) according to claim 8,
wherein the demultiplexer unit (24) has a plurality of optical switches (28) that are arranged in series one after the other in the beam path of the input laser beam (20),
wherein each optical switch (28) in a switched position is configured to form a respective laser writing beam (26) by decoupling a portion of the laser beam sufficient to transfer the lithographic material (12) into an exposed state.

11. The laser lithography device (10) according to claim 8,
wherein the demultiplexer unit (24) comprises an optical switch (28) which is arranged in the beam path of the input laser beam (20) downstream of the laser beam source (18),
wherein the demultiplexer unit (24) has an optical arrangement which is configured to guide the input laser beam (20) several times through the optical switch (28),
wherein the optical switch (28) in a switched position is configured to form a laser writing beam (26) by decoupling a portion of the laser beam sufficient to transfer the lithographic material (12) into an exposed state.

12. The laser lithography device (10) according to claim 8,
wherein the laser lithography device (10) comprises a power detection unit (32) for detecting a power of the input laser beam (20) in the beam path downstream of the demultiplexer unit (24),
wherein the laser lithography device (10) comprises a control unit (30) that is configured to control the demultiplexer unit (24) for the purpose of forming the plurality of laser writing beams (26) by demultiplexing the input laser beam (20) as a function of the detected power.

13. The laser lithography device (10) according to claim 8,
wherein the laser lithography device (10) comprises a waveguide arrangement (54) which has a plurality of waveguides (56) for guiding the plurality of laser writing beams (26), wherein in each case one waveguide (56) is assigned to a laser writing beam (26),
wherein the waveguides (56) are arranged in the beam path between the demultiplexer unit (24) and the objective (70),
wherein each waveguide (56) has a first end (58) and a second end (60) opposite the first end (58),
wherein each first end (58) is configured to couple-in a laser writing beam (26), and each second end (60) is configured to decouple the laser writing beam (26) coupled into the first end (58),
wherein the second ends (60) of the plurality of waveguides (56) are held by a holding matrix (62) of the waveguide arrangement (54).

14. The laser lithography device (10) according to claim 13,
wherein the second ends (60) of the plurality of waveguides (56) are held by the holding matrix (62) in a linear arrangement or in a two-dimensional arrangement.

15. The laser lithography device (10) according to claim 13,
wherein the distance between two adjacent second ends (60) of the plurality of waveguides (56) is 25 μm to 1000 μm, in particular 115 μm to 600 μm.

16. The laser lithography device (10) according to claim 13,
wherein each second end (60) of the plurality of waveguides (56) has an end face which is configured to decouple the laser writing beam (26) coupled into the first end (58),
wherein the end faces of the second ends (60) are arranged in one plane.

17. The laser lithography device (10) according to claim 13,
wherein the scanning apparatus (78) is configured to shift the foci (72) relative to the lithographic material holder (14) by shifting the holding matrix (62).

18. The laser lithography device (10) according to claim 13,
wherein each waveguide (56) is configured as an optical hollow-core fiber.

19. The laser lithography device (10) according to claim 13,
wherein each waveguide (56) is selected from the group comprising: HC PCF fibers, in particular HC kagome fibers, HC PBGF fibers, HC ARF fibers, HC IC fibers, RH fibers, LMA fibers, PCF fibers.
